(19) United States
(12) Patent Application Publication
(10) Pub. No.: US 2021/0327909 A1
(43) Pub. Date: Oct. 21, 2021

(54) ARRAY SUBSTRATE, MANUFACTURING METHOD THEREOF, AND DISPLAY DEVICE

(71) Applicant: Yuan Yan, Wuhan (CN)

(72) Inventor: Yuan Yan, Wuhan (CN)

(73) Assignees: WUHAN CHINA STAR OPTOELECTRONICS TECHNOLOGY CO., LTD., Wuhan (CN); WUHAN CHINA STAR OPTOELECTRONICS TECHNOLOGY CO., LTD., Wuhan (CN)

(21) Appl. No.: 16/620,548

(22) PCT Filed: Jun. 12, 2019
(86) PCT No.: PCT/CN2019/090946

§ 371 Date: Dec. 9, 2019

(30) Foreign Application Priority Data
May 30, 2019 (CN) 201910465496.2

(51) Int. Cl. H01L 27/12

(52) U.S. Cl. CPC H01L 27/124; H01L 27/127; H01L 27/1237

(57) ABSTRACT

An array substrate, a manufacturing method of the array substrate, and a display device are provided. A first metal layer of the array substrate includes first gate lines arranged in parallel and spaced relationship. A second metal layer includes data lines arranged in parallel and spaced relationship and at least one second gate line spaced from the data lines. The first gate lines are vertical to the data lines and intersect them. Each second gate line is above a corresponding one of the first gate lines. Each via hole set of the insulating layer is arranged corresponding to each second gate line. Each via hole set includes at least two via holes spaced from each other. Each second gate line contacts the first gate line under it via a corresponding via hole set.

### 1. FIELD OF DISCLOSURE

The present invention relates to a field of display devices and in particular, to an array substrate, a manufacturing method thereof, and a display device.

### 2. DESCRIPTION OF RELATED ART

Liquid crystal displays (LCDs) have many advantages such as being thin, power saving, no radiation, etc., and are used in a wide range of applications such as mobile phones, personal digital assistants (PDAs), digital cameras, computer screens, and laptops.

Most of the LCD devices on the market are backlight-type LCD devices which include a casing, a LCD panel disposed in the casing, and a backlight module disposed in the casing. Conventional LCD panels are composed of a color filter substrate, a thin film transistor array substrate (TFT array substrate), and a liquid crystal layer disposed between the two substrates. The working principle of the LCDs is that rotation of the liquid crystal molecules of the liquid crystal layer is controlled by applying a driving voltage between two glass substrates, and light of the backlight module is refracted to generate images.

Referring to FIGS. 1 and 2, a conventional array substrate includes a base layer 100, a first metal layer 200, an insulating layer 300, and a second metal layer 400 disposed in sequence. The first metal layer 200 includes multiple gate lines 210 arranged parallel to and spaced from each other and multiple gate electrodes 220. The second metal layer 400 includes multiple data lines 410 arranged parallel to and spaced from each other and multiple source/drain electrodes (not illustrated). The gate lines 210 intersect perpendicularly with the data lines 410 to define a plurality of pixel regions. With the development of display technology, LCD devices are larger in size, resulting in higher resolutions and higher aperture ratios, which increases impedance and load of the gate lines, thus affecting product quality.

### SUMMARY

It is an objective of the present invention to provide an array substrate which can reduce an impedance of a gate line and improving product quality.

It is another objective of the present invention to provide a manufacturing method of an array substrate, which can reduce an impedance of a gate line and improve product quality.

It is still another objective of the present invention to provide a display device which can reduce an impedance of a gate line and improve product quality.

Accordingly, the present invention provides an array substrate. The array substrate comprises a first metal layer, an insulating layer disposed on the first metal layer, and a second metal layer disposed on the insulating layer. The first metal layer comprises multiple first gate lines arranged parallel to and spaced apart from each other. The second metal layer comprises multiple data lines in parallel and spaced relationship to each other and at least one second gate line spaced apart from the data lines. The first gate lines are arranged vertical to the data lines and intersect the same. Each of the second gate lines is disposed above a corresponding one of the first gate lines. The insulating layer includes a plurality of via hole sets, and each via hole set is arranged corresponding to each of the second gate lines. Each via hole set comprises at least two via holes spaced apart from each other Each second gate line is in contact with the first gate line thereunder via a corresponding one of the via hole sets.

The array substrate comprises multiple second gate lines, and each second gate line is disposed above each first gate line between adjacent two of the data lines.

The array substrate further comprises a base layer, and the first metal layer is disposed on the base layer.

The at least one second gate line is parallel to the first gate lines.

Each via hole set comprises two via holes spaced apart from each other, and two ends of each second gate line are in contact with the first gate line thereunder via corresponding two of the via holes.

The present invention provides a manufacturing method of an array substrate, comprising steps as follows.

Step S1: providing a substrate, in which a first metal film is formed on the substrate and patterned to form a first metal layer, and the first metal layer comprises multiple first gate lines arranged parallel to each other in a spaced-apart manner;

Step S2: forming an insulating layer on the first metal layer and patterning the insulating layer to form at least one via hole set, wherein each via hole set comprises at least two via holes spaced apart from each other, and each via hole set is disposed above a corresponding one of the first gate lines; and Step S3: forming a second metal film on the insulating layer and patterning the second metal film to form a second metal layer, wherein the second metal layer comprises multiple data lines arranged parallel to each other in a spaced-apart manner and at least one second gate line spaced apart from the data lines; the first gate lines are arranged vertical to the data lines and intersect the same; each second gate line is disposed above a corresponding one of the first gate lines and arranged corresponding to one corresponding via hole set; and each second gate line is in contact with the first gate line thereunder via one corresponding via hole set.

The array substrate comprises multiple second gate lines, and each second gate line is disposed above each first gate line between adjacent two of the data lines.

The at least one second gate line is arranged parallel to the first gate lines.

Each via hole set comprises two via holes spaced apart from each other, and two ends of each second gate line are in contact with the first gate line thereunder via corresponding two of the via holes.

The present invention further provides a display device which comprises the array substrate mentioned above.

Advantages of the present invention:

The present invention provides an array substrate. A first metal layer of the array substrate comprises multiple first gate lines arranged parallel to and spaced apart from each other. The second metal layer comprises multiple data lines in parallel and spaced relationship to each other and at least one second gate line spaced apart from the data lines. The first gate lines are arranged vertical to the data lines and intersect the same. Each of the second gate lines is disposed above a corresponding one of the first gate lines. The insulating layer includes a plurality of via hole sets, each via hole set is arranged corresponding to each second gate line, and each via hole set comprises at least two via holes spaced apart from each other. Each second gate line is in contact with the first gate line thereunder via a corresponding one of the via hole sets. Such configuration lowers an impedance of a gate line constituted by the first gate line and the second gate line and improves product quality. A manufacturing method of a thin-film transistor array substrate of the present invention lowers the impedance of the gate line and improves product quality. A display device of the present invention lowers the impedance of the gate line and improves product quality.

### BRIEF DESCRIPTION OF DRAWINGS

In order to further understand the features and technical contents of the present invention, please refer to the following detailed description of the invention and the accompanying drawings. The accompanying drawings are provided for purposes of illustration and description only, and are not intended to be limiting. In the drawings,

FIG. 1 is a schematic top view partially illustrating a conventional array substrate;

FIG. 2 is a cross-sectional view taken along line A-A′ of FIG. 1;

FIG. 3 is a schematic top view partially illustrating an array substrate of the present invention;

FIG. 4 is a schematic cross-sectional view taken along line B-B′ of FIG. 3;

FIG. 5 is a process flow diagram illustrating a manufacturing method of the array substrate;

FIG. 6 is a schematic view illustrating step S1 in the manufacturing method of the array substrate; and

FIG. 7 is a schematic view illustrating step S2 in the manufacturing method of the array substrate.

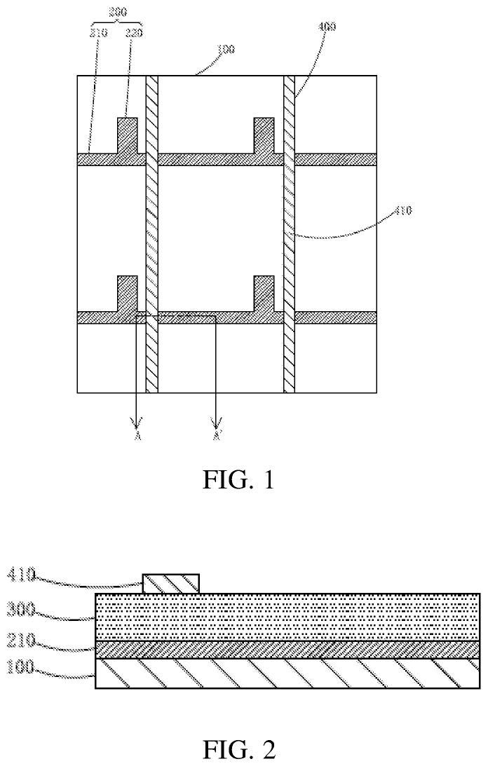

### DETAILED DESCRIPTION OF EMBODIMENTS

In order to further describe the technical solutions and functions of the present invention, the following detailed description is made in conjunction with some embodiments of the invention and the accompanying drawings.

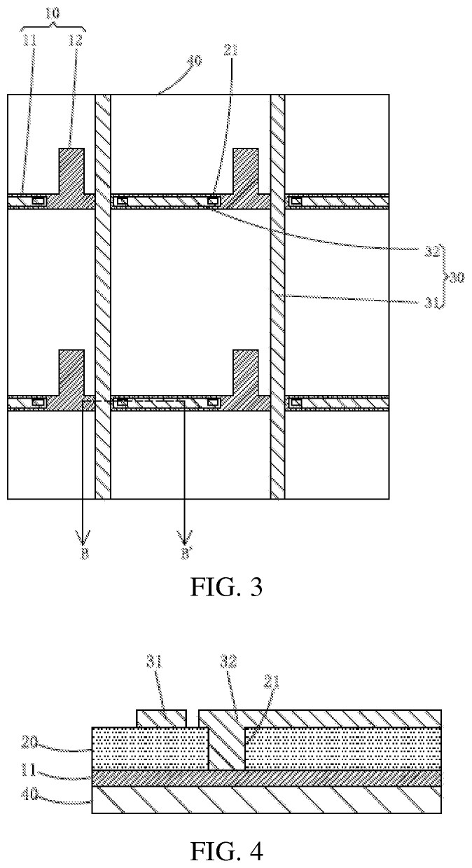

Referring to FIGS. 3 and 4, the present invention provides an array substrate. The array substrate comprises a first metal layer 10, an insulating layer 20 disposed on the first metal layer 10, and a second metal layer 30 disposed on the insulating layer 20.

The first metal layer 10 comprises multiple first gate lines 11 arranged parallel to and spaced apart from each other. The second metal layer 30 comprises multiple data lines 31 arranged in parallel and spaced relationship to each other and at least one second gate line 32 spaced apart from the data lines 31. The first gate lines 11 are arranged vertical to the data lines 31 and intersect the same to form multiple pixel regions. Each of the second gate lines 32 is disposed above a corresponding one of the first gate lines 11. The insulating layer 20 includes a plurality of via hole sets, each via hole set is arranged corresponding to each of the second gate lines 32. Each via hole set 21 comprises at least two via holes 21 spaced apart from each other. Each second gate line 32 is in contact with the first gate line 11 thereunder via a corresponding one of the via hole sets.

Referring to FIG. 3, in detail, the array substrate comprises multiple second gate lines 32, and each second gate line 32 is disposed above each first gate line 11 between adjacent two of the data lines 31.

Referring to FIGS. 3 and 4, the array substrate further comprises a base layer 40. The first metal layer 10 is disposed on the base layer 40. The base layer 40 comprises an effective display region and a non-display region outside the effective display region. The first gate lines 11, the data lines 31, and the second gate lines 32 are disposed in the effective display region.

Referring to FIG. 3, it is preferable that the second gate lines 32 are parallel to the first gate lines 11.

Referring to FIG. 3, it is preferable that each via hole set comprises at least two via holes 21 spaced apart from each other; two ends of each second gate line 32 are in contact with the first gate line 11 thereunder via corresponding two of the via holes 21.

Referring to FIG. 3, the first metal layer 10 further comprises multiple gate electrodes 12 which are arrayed. Each gate electrode 12 is disposed corresponding to one of the pixel regions. The gate electrodes 12 in a same row are connected to one of the first gate lines 11. The array substrate further comprises multiple active layers (not illustrated) which are arrayed on the substrate, and a barrier layer (not illustrated) on the active layers and the substrate 40. The first metal layer 10 is disposed on the barrier layer. Each gate electrode 12 is disposed above a corresponding one of the active layers. The second metal layer 30 further comprises multiple source electrodes and multiple drain electrodes (not illustrated) arranged corresponding to the gate electrodes 12. Two ends of the active layer disposed corresponding to each gate electrode 12 are connected to the source electrode and the drain electrode disposed corresponding to the gate electrode 12. The source electrodes disposed corresponding to the gate electrodes 12 in a same row are connected to a same one of the data lines 31. Accordingly, the corresponding gate electrode, active layer, source electrode, and drain electrode together constitute a thin-film transistor.

Besides multiple data lines 31, the second metal layer 30 of the array substrate of the present invention also has at least one second gate line 32. The via holes 21 are defined in the insulating layer 20 between the first metal layer 10 and the second metal layer 30. Each second gate line 32 is in contact with the first gate line 11 thereunder via a corresponding via hole set, so that each second gate line 32 and each first gate line 11 thereunder are connected in parallel. As a result, a gate line constituted by the first gate line 11 and the second gate line 32 connected in parallel has a lower impedance compared to an impedance of a conventional gate line which is disposed in a first metal layer only, so product quality is improved. The second gate line 32 and the first gate line 11 disposed thereunder are connected in parallel instead of being disconnected from each other. Such configuration prevents an open-circuit of the gate line (constituted by the second gate lines 32 and the first gate lines 11) caused by poor contact between that the second gate line 32 and the first gate line 11, thus improving production yields and improving antistatic capabilities of the gate line.

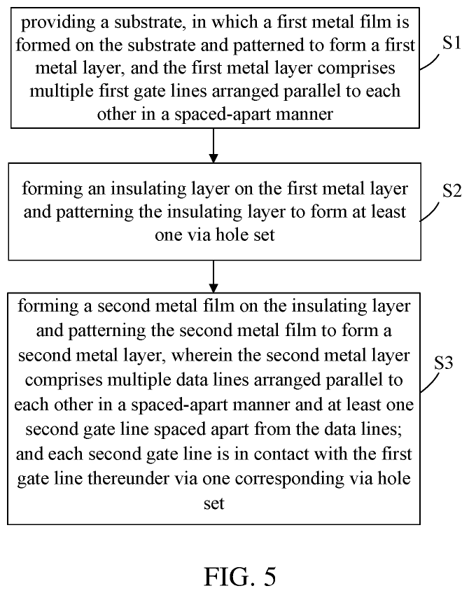

Please refer to FIG. 5. Based on the same inventive concept, the present invention further provides a manufacturing method of an array substrate, comprising steps as follows.

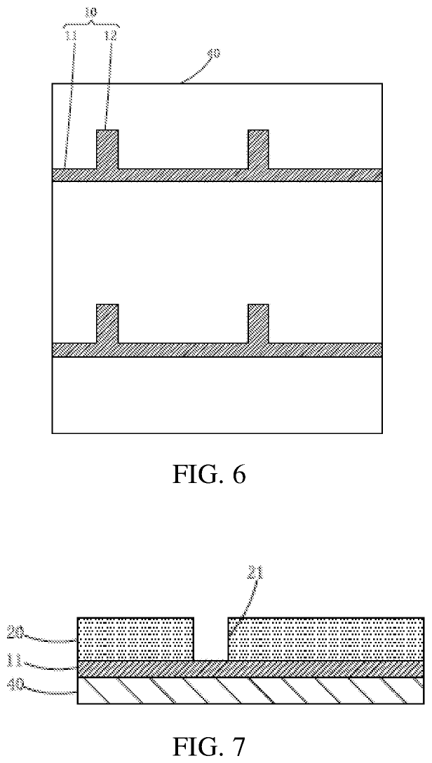

Step S1 as shown in FIG. 6, providing a substrate 40, in which a first metal film is formed on the substrate 40 and patterned to form a first metal layer 10, and the first metal layer 10 comprises multiple first gate lines 11 arranged parallel to each other in a spaced-apart manner.

In detail, the substrate 40 comprises an effective display region and a non-display region outside the effective display region. The first gate lines 11 are disposed in the effective display region.

Referring to FIG. 6, the first metal layer 10 further comprises multiple gate electrodes 12 which are arrayed. The gate electrodes 12 in a same row are connected to a corresponding one of the first gate lines 11.

Moreover, in step S1, multiple active layers (not illustrated) which are arrayed are formed on the substrate 40, and a barrier layer (not illustrated) is formed on the active layers and the substrate 40. The first metal film is formed on the barrier layer. The gate electrodes 12 are correspondingly disposed above the active layers, respectively.

Step S2: as shown in FIG. 7 in conjunction with FIG. 3, forming an insulating layer 20 on the first metal layer 10 and patterning the insulating layer 20 to form at least one via hole set, wherein each via hole set comprises at least two via holes 21 spaced apart from each other, and each via hole set is disposed above a corresponding one of the first gate lines 11.

Referring to FIG. 3, each via hole set preferably has two via holes 21 spaced apart from each other.

Step S3: forming a second metal film on the insulating layer 20 and patterning the second metal film 30 (see FIGS. 3 and 4) to form a second metal layer 30, wherein the second metal layer 30 comprises multiple data lines 31 arranged parallel to each other in a spaced-apart manner and at least one second gate line 32 spaced apart from the data lines 31; the first gate lines 11 are arranged vertical to the data lines 31 and intersect the same; each second gate line 32 is disposed above a corresponding one of the first gate lines 11 and arranged, corresponding to one corresponding via hole set; and each second gate line 32 is in contact with the first gate line 11 thereunder via one corresponding via hole set.

Referring to FIG. 3, the array substrate comprises multiple second gate lines 32, and each second gate line 32 is disposed above each first gate line 11 between adjacent two of the data lines 31.

Moreover, the data lines 31 and the second gate lines 32 are disposed in the effective display region.

Referring to FIG. 3, it is preferable that, the second gate lines 32 are parallel to the first gate lines 11.

Referring to FIG. 3, it is preferable that, two ends of each second gate line 32 are in contact with the first gate line 11 thereunder via corresponding two of the via holes 21.

Specifically, referring to FIG. 3, the second metal layer 30 further comprises multiple source electrodes and multiple drain electrodes (not illustrated), arranged corresponding to the gate electrodes 12. Two ends of the active layer disposed corresponding to each gate electrode 12 are connected to the source electrode and the drain electrode arranged corresponding to the gate electrode 12. The source electrodes disposed corresponding to the gate electrodes 12 in a same TOW are connected to a same one of the data lines 31, so that the corresponding gate electrode 12, active layer, source electrode, and drain electrode together constitute a thin-film transistor.

In the manufacturing of the array substrate, the second metal layer 30 of the array substrate also has at least one second gate line 32 in addition to multiple data lines 31. The via holes 21 are defined in the insulating layer 20 between the first metal layer 10 and the second metal layer 30. Each second gate line 32 is in contact with each first gate line 11 thereunder via a corresponding via hole set, and thereby the second gate lines 32 and the first gate lines 11 thereunder are connected in parallel. Accordingly, a gate line constituted by the first gate line 11 and the second gate line 32 connected in parallel has a much lower impedance than an impedance of a conventional gate line which is only disposed in a first metal layer, and as a result, product quality is improved. Moreover, the second gate line 32 and the first gate line 11 thereunder are connected in parallel instead of being disconnected from each other. This prevents an open-circuit of the gate lines (constituted by the second gate lines 32 and the first gate lines 11) resulting from poor contact between the second gate lines 32 and the first gate lines 11, thus improving production yields and improving antistatic capabilities of the gate lines.

The present invention further provides a display device based on the same inventive concept. The display device comprises the array substrate mentioned above. Therefore, a description regarding the structure of the array substrate is not repeated herein for brevity. The display device can be a conventional common display device having an array substrate, such as a liquid crystal display device and an organic light-emitting diode display device.

It should be noted that, in the display device of the present invention, the second metal layer 20 of the array substrate has at least one second gate line 32 besides multiple data lines 31. The via holes 21 are defined in the insulating layer 20 between the first metal layer 10 and the second metal layer 30. Each second gate line 32 is in contact with each first gate line 11 thereunder via a corresponding via hole set, and thereby the second gate lines 32 and the first gate lines 11 thereunder are connected in parallel. Accordingly, a gate line constituted by the first gate line 11 and the second gate line 32 connected in parallel has a much lower impedance than an impedance of a conventional gate line which is only disposed in a first metal layer, and as a result, product quality is improved. Moreover, the second gate line 32 and the first gate line 11 thereunder are connected in parallel instead of being disconnected from each other. This prevents an open-circuit of the gate lines (constituted by the second gate lines 32 and the first gate lines 11) resulting from poor contact between the second gate lines 32 and the first gate lines 11, thus improving production yields and improving antistatic capabilities of the gate line.

In summary, the present invention provides an array substrate. A first metal layer of the array substrate comprises multiple first gate lines arranged parallel to and spaced apart from each other. The second metal layer comprises multiple data lines in parallel and spaced relationship to each other and at least one second gate line spaced apart from the data lines. The first gate lines are arranged vertical to the data lines and intersect the same. Each of the second gate lines is disposed above a corresponding one of the first gate lines. The insulating layer includes a plurality of via hole sets, each via hole set is arranged corresponding to each second gate line, and each via hole set comprises at least two via holes spaced apart from each other. Each second gate line is in contact with the first gate line thereunder via a corresponding one of the via hole sets. Such configuration lowers an impedance of a gate line constituted by the first gate line and the second gate line and improves product quality. A manufacturing method of a thin-film transistor array substrate of the present invention lowers impedance of the gate line and improves product quality. A display device of the present invention lowers impedance of the gate line and improves product quality.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. An array substrate, comprising:
a first metal layer;
an insulating layer disposed on the first metal layer; and
a second metal layer disposed on the insulating layer;
wherein the first metal layer comprises multiple first gate lines arranged parallel to and spaced apart from each other; the second metal layer comprises multiple data lines in parallel and spaced relationship to each other and at least one second gate line spaced apart from the data lines; the first gate lines are arranged vertical to the data lines and intersect the same; each of the second gate lines is disposed above a corresponding one of the first gate lines; the insulating layer includes a plurality of via hole sets, each via hole set is arranged corresponding to each second gate line; each via hole set comprises at least two via holes spaced apart from each other; and each second gate line is in contact with the first gate line thereunder via a corresponding one of the via hole sets.

2. The array substrate according to claim 1, wherein the array substrate comprises multiple second gate lines, and each second gate line is disposed above each first gate line between adjacent two of the data lines.

3. The array substrate according to claim 1, further comprising a base layer, the first metal layer being disposed on the base layer.

4. The array substrate according to claim 1, wherein the at least one second gate line is parallel to the first gate lines.

5. The array substrate according to claim 1, wherein each via hole set comprises two via holes spaced apart from each other, and two ends of each second gate line are in contact with the first gate line thereunder via corresponding two of the via holes.

6. A manufacturing method of an array substrate, comprising steps as follows:
step S1: providing a substrate, in which a first metal film is formed on the substrate and patterned to form a first metal layer, and the first metal layer comprises multiple first gate lines arranged parallel to each other in a spaced-apart manner;
step S2: forming an insulating layer on the first metal layer and patterning the insulating layer to form at least one via hole set, wherein each via hole set comprises at least two via holes spaced apart from each other, and each via hole set is disposed above a corresponding one of the first gate lines; and
step S3: forming a second metal film on the insulating layer and patterning the second metal film to form a second metal layer, wherein the second metal layer comprises multiple data lines arranged parallel to each other in a spaced-apart manner and at least one second gate line spaced apart from the data lines; the first gate lines are arranged vertical to the data lines and intersect the same; each second gate line is disposed above a corresponding one of the first gate lines and arranged corresponding to one corresponding via hole set; and each second gate line is in contact with the first gate line thereunder via one corresponding via hole set.

7. The manufacturing method of the array substrate according to claim 6, wherein the array substrate comprises multiple second gate lines, and each second gate line is disposed above each first gate line between adjacent two of the data lines.

8. The manufacturing method of the array substrate according to claim 6, wherein the at least one second gate line is arranged parallel to the first gate lines.

9. The manufacturing method of the array substrate according to claim 6, wherein each via hole set comprises two via holes spaced apart from each other, and two ends of each second gate line are in contact with the first gate line thereunder via corresponding two of the via holes.

10. A display device, comprising the array substrate of claim 1.
